(19) United States
(12) Patent Application Publication
(10) Pub. No.: US 2002/0094057 A1
(43) Pub. Date: Jul. 18, 2002

(54) Shift register

(76) Inventor: Yoshihiro Shibuya, Chiba-shi (JP)

Correspondence Address: ADAMS & WILKS, ATTORNEYS AND COUNSELORS AT LAW, 31st FLOOR, 50 BROADWAY, NEW YORK, NY, 10004, US

(21) Appl. No.: 10/017,246

(22) Filed: Dec. 13, 2001

(30) Foreign Application Priority Data
Jan. 10, 2001 (JP) 2001-002440

(51) Int. Cl. G11C 19/00

(52) U.S. Cl. 377/67

(57) ABSTRACT

It is intended to eliminate a malfunction caused by racing, to minimize the time of delay of output from a shift register with respect to an oscillating clock signal, and to reduce the output delay time difference in the shift register. A shift register is provided, which is divided into blocks using a plurality of flip flops and a clock buffer. In the shift register, a plurality of basic cells are arranged serially so that a clock signal is supplied from an opposite direction to that of data flow.

### BACKGROUND OF THE INVENTION

1. Field of the Invention

The present invention relates to a shift register in which a malfunction that occurs due to racing caused by the difference in propagation time between a clock and data is eliminated, a time of delay of output from the shift register with respect to an oscillating clock signal is minimized, and the output delay time difference in the shift register is reduced.

2. Description of the Related Art

When a shift register circuit for a plurality of BITs is configured using flip flops each of which takes in data on the rising or falling edge of a clock signal to produce an output, it is conceivable that in the case where a flip flop on the data transmission side starts before a flip flop on the data reception side does, logic of the data output from the flip flop on the transmission side has already been varied at a point of time when input data are read in by the flip flop on the data reception side. In such a case, the circuit malfunctions. The phenomenon that a malfunction is caused through the output from a flip flop on the data transmission side prior to output from a flip flop on the data reception side as described above is referred to as “racing”.

In the conventional technique, a clock signal as a reference is distributed in a chip without skewing. Hence, a clock transmission path is formed in a treelike or netlike form, and delay is provided so that delay conditions of the clock signal in the clock transmission path to a plurality of flip flops become equal among the plurality of flip flops as far as possible. Thus, the racing is prevented.

Furthermore, a delay circuit is provided between a flip flop on the data transmission side and a flip flop on the data reception side to delay data output from the flip flop on the data transmission side. Thus, the racing is prevented.

In a conventional shift register shown in FIG. 4, a clock is supplied from an opposite direction to that of data flow and thus the racing is prevented.

However, in such measures against the racing in a shift register, the time of delay of outputs from flip flops with respect to an oscillating clock signal increases. FIG. 5 shows timing of a clock signal with respect to each flip flop in the shift register with the configuration shown in FIG. 4 according to the conventional technique.

In a wiring line for supplying a clock signal, parasitic capacitance and parasitic resistance indicated as RC are generated between adjacent flip flops. This increases the time of delay of the clock signal with distance from a clock buffer. A delay time difference of td101 is caused between a clock input signal C108 input to a flip flop 108 disposed in a position nearest to the clock buffer and a clock input signal C101 input to a flip flop 101 disposed in a position farthest from the clock buffer. For instance, in a semiconductor device with a light-receiving element contained therein such as a photoelectric conversion device, since the time of delay of output from a shift register with respect to an oscillating clock signal increases, a high-speed operation cannot be achieved. In addition, since the output delay time difference is caused in the shift register, the difference in light-receiving time is caused and thus the fluctuation among BITs is caused.

### SUMMARY OF THE INVENTION

A shift register according to the present invention is characterized by; allowing a malfunction due to racing to be eliminated; being divided into blocks each of which includes a plurality of flip flops and a clock inverter in order to minimize the difference in time of delay of output from the shift register with respect to an oscillating clock signal; supplying a clock signal from an opposite direction to that of data flow; and serially arranging a plurality of basic cells that are divided into blocks.

### BRIEF DESCRIPTION OF THE DRAWINGS

In the accompanying the drawings:

FIG. 1 is a circuit diagram showing a shift register according to Embodiment 1 of the present invention;

FIG. 2 is a layout drawing showing a shift register according to Embodiment 2 of the present invention;

FIG. 3 is a timing chart as to the shift register according to Embodiment 1 of the present invention;

FIG. 4 is a circuit diagram showing a conventional shift register; and

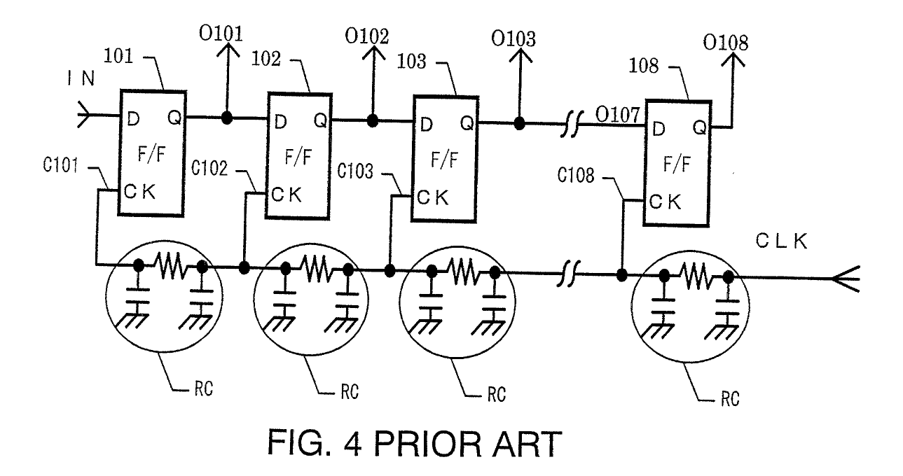

FIG. 5 is a timing chart as to the conventional shift register.

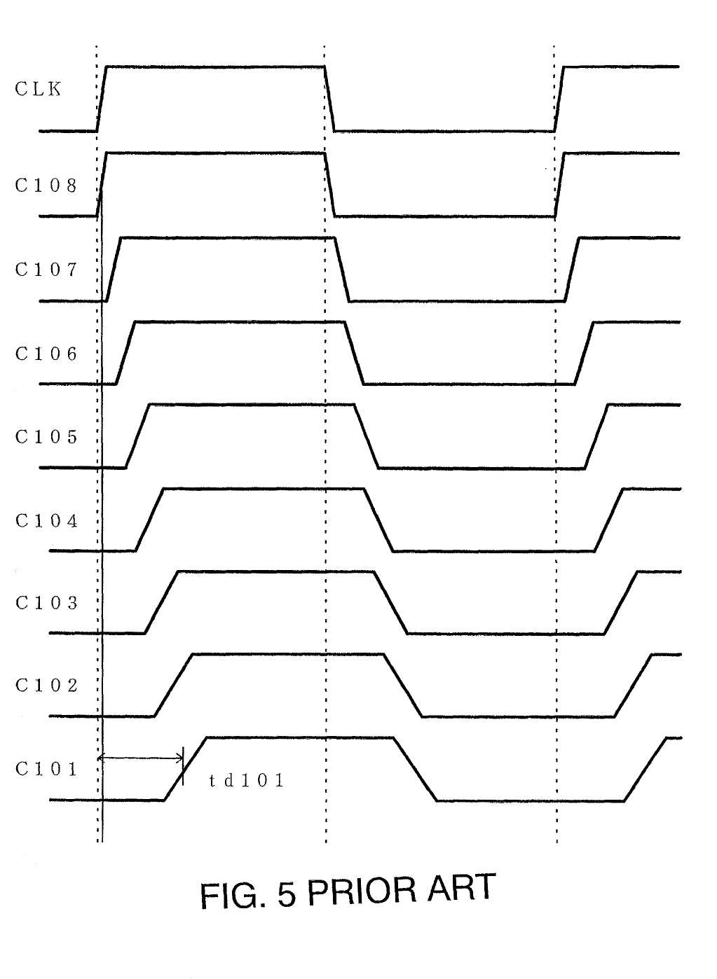

### DETAILED DESCRIPTION OF THE PREFERRED EMBODIMENTS

A shift register according to the present invention allows a malfunction due to racing to be eliminated through the division of the shift register into blocks using a plurality of flip flops and a clock inverter and through the serial arrangement of a plurality of basic cells to which a clock signal is supplied from an opposite direction to that of data flow. As a result, the time of delay of output from the shift register with respect to an oscillating clock signal can be minimized and the output delay time difference in the shift register can be reduced.

### EMBODIMENT 1

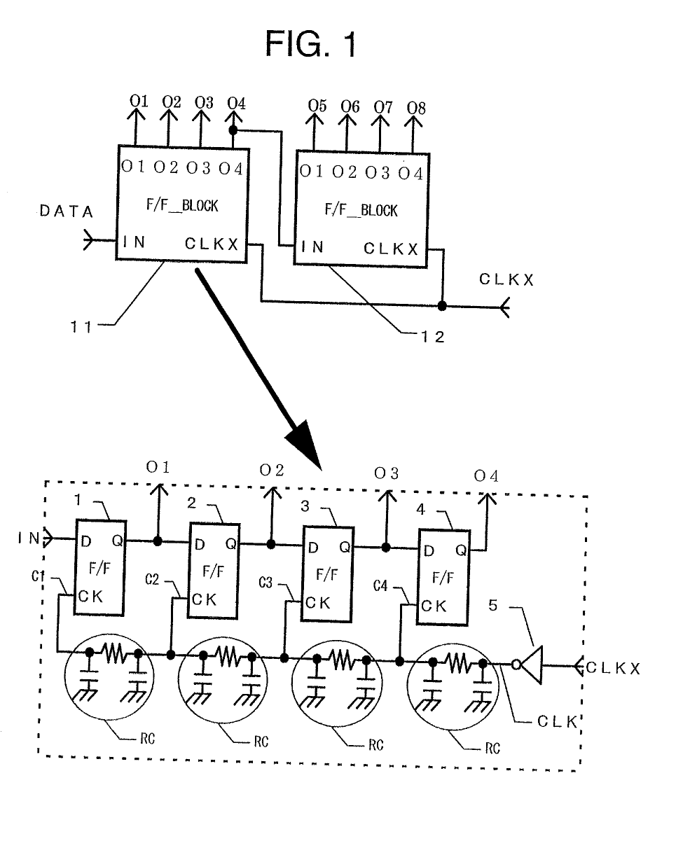

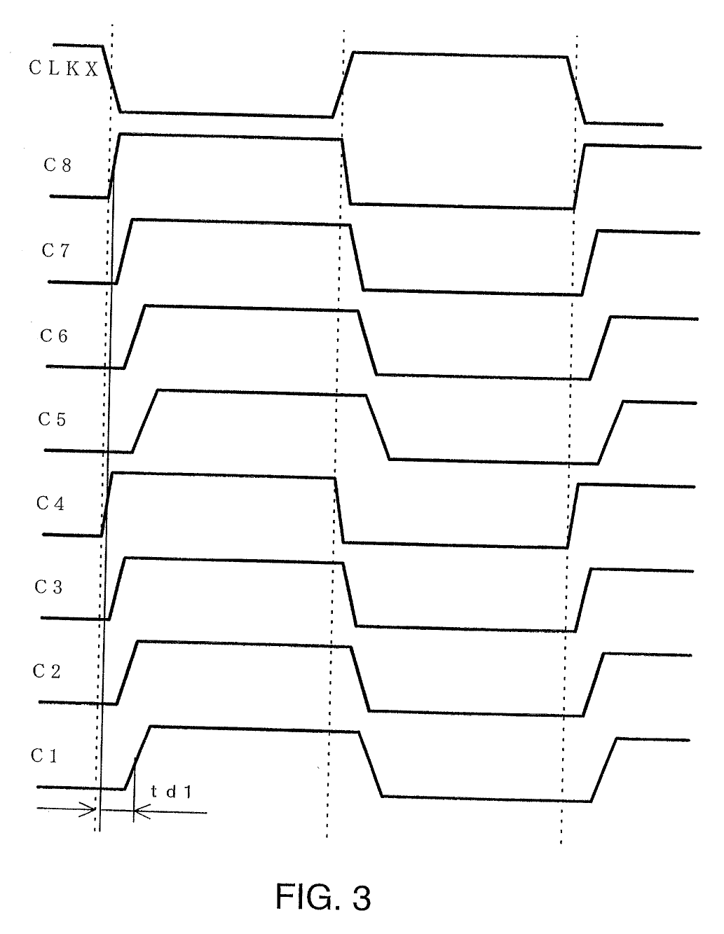

FIG. 1 is a circuit diagram showing a shift register according to Embodiment 1 of the present invention. FIG. 3 shows an example of timing in respective signal lines according to Embodiment 1 of the present invention.

A flip flop as a basic cell is used in which a data signal is input to a data input D, data is taken in on the rising or falling edge of a clock signal input to a clock input CK, and an output signal Q for producing an output is provided. For convenience of description, in this case, data are taken in in synchronization with the rising edge of a clock signal input to the clock input CK and then the output signal Q is output.

A data signal IN is input to a data input D of a flip flop 1 and then an output O1 is output from an output signal Q. In a flip flop 2, the output O1 from the flip flop 1 is input to a data input D and an output O2 is output from an output signal Q. In a flip flop 3, the output O2 from the flip flop 2 is input to a data input D and an output O3 is output from an output signal Q. In a flip flop 4, the output O3 from the flip flop 3 is input to a data input D and an output O4 is output from an output signal Q. In a clock buffer 5 for shaping a clock signal, an oscillating clock signal CLKX is input and a clock signal CLK′ as a reversed signal is output. The clock signal CLK′ is led to the respective clock inputs CK of the flip flops 1 to 4. In this case, parasitic resistance and parasitic capacitance are generated in the clock signal CLK′ and thus clock signals C1, C2, C3, and C4 are input to clock inputs CK of the flip flops 1, 2, 3, and 4, respectively. The clock signals are input sequentially to the flip flops 4, 3, 2, and 1. The connection is established in this manner and thus a basic circuit F/F_BLOCK of the shift register is configured. For convenience of description, an inverter was used as the clock buffer 5 for shaping the clock signal composing the basic circuit of the shift register. However, the clock buffer 5 may be a buffer or another circuit as a means for shaping an oscillating clock signal and then supplying it to the flip flops. Furthermore, the basic circuit F/F_BLOCK of the shift register includes four serially-connected flip flops in this case but may include a plurality of serially-connected flip flops such as two or three serially-connected flip flops.

When the shift register is configured with the connection established as described above, as for the effect on racing, the clock signal C1 of the flip flop 1 delays without fail due to the influence of the parasitic capacitance and resistance as compared to the clock signal C2 of the flip flop 2. Hence, before the output signal O1 is output from the flip flop 1 on the data transmission side, the flip flop 2 on the data reception side can take in data. As compared to the clock signal C3 of the flip flop 3, the clock signal C2 of the flip flop 2 delays without fail due to the influence of the parasitic capacitance and resistance. Hence, before the output signal O2 is output from the flip flop 2 on the data transmission side, the flip flop 3 on the data reception side can take in data. Similarly, as compared to the clock signal C4 of the flip flop 4, the clock signal C3 of the flip flop 3 delays without fail due to the influence of the parasitic capacitance and resistance. Hence, before the output signal O3 is output from the flip flop 3 on the data transmission side, the flip flop 4 on the data reception side can take in data. In this manner, a clock signal is input to a flip flop on the data reception side before a clock signal is input to a flip flop on the data transmission side. This prevents a flip flop on the data reception side from receiving output data from a flip flop on the transmission side by mistake.

A data signal DATA is input to a data input signal IN of a basic circuit F/F_BLOCK 11 of the shift register and then the outputs O1 to O4 are produced in synchronization with the falling edge of the oscillating clock signal CLKX. A basic circuit F/F_BLOCK 12 of the shift register is disposed, which is serially connected with the basic circuit F/F_BLOCK 11 of the shift register. As a data signal, the output O4 as a final output from the basic circuit F/F_BLOCK 11 of the register is input to a data input signal IN of the basic circuit F/F_BLOCK 12. Then, outputs O5 to O8 are produced in synchronization with the falling edge of the oscillating clock signal CLKX. For convenience of description, the shift register includes two serially-connected basic circuits F/F_BLOCK but may include three serially-connected basic circuits F/F_BLOCK or more.

Through the serial connection of the basic circuits F/F_BLOCK as described above, a delay time difference td1 was obtained with respect to the oscillating clock signal CLKX. With the shift register divided into blocks, the output from the shift register was produced with a minimum delay time with respect to the oscillating clock signal and the output delay time difference in the shift register was also reduced.

### Embodiment 2

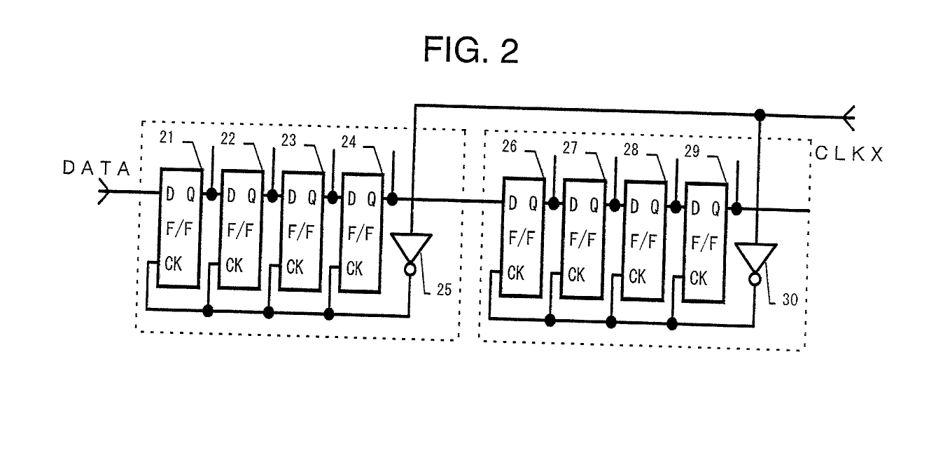

FIG. 2 shows a layout drawing illustrating the case where the shift register according to Embodiment 1 of the present invention is disposed on a semiconductor substrate actually.

When data are shifted from left to right, a flip flop 21 into which a data signal DATA is input is disposed leftmost. Then, flip flops 22 to 24 are disposed sequentially. A clock buffer 25 is disposed next to the flip flop 24. The flip flops 21 to 24 and the clock buffer 25 are composed of one basic circuit of the shift register. Similarly, flip flops 26 to 29 and a clock buffer 30 are arranged. A shift register thus configured is disposed. Through the disposition on one band in this manner, the register can be disposed effectively, particularly, in a product with an elongated chip shape such as a line-type photoelectric conversion device.

The present invention is implemented with the configuration described above and provides excellent effects described as follows. A shift register is divided into blocks using a plurality of flip flops and a clock buffer. The shift register includes a plurality of serially-connected basic cells arranged so as to supply a clock signal from an opposite direction to that of data flow. With this configuration, the present invention provides the effects of eliminating a malfunction due to racing, minimizing the time of delay of output from the shift register with respect to an oscillating clock signal, and reducing the output delay time difference in the shift register.

The present invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A shift register, comprising blocks as a plurality of basic circuits each of which includes a plurality of flip flops and a clock buffer for supplying a clock signal to the flip flops, the plurality of basic circuits being arranged serially in which the clock signal is supplied from an opposite direction to that of data flow.

2. A semiconductor device, comprising a shift register according to claim 1 disposed on one band.

3. A semiconductor device, comprising a shift register according to claim 1 used in a line-type photoelectric conversion device.

4. A semiconductor device, comprising a shift register according to claim 2 used in a line-type photoelectric conversion device.
